(19) United States
(12) Patent Application Publication
(10) Pub. No.: US 2010/0227459 A1
(43) Pub. Date: Sep. 9, 2010

(54) METHOD FOR FORMING W-BASED FILM, METHOD FOR FORMING GATE ELECTRODE, AND METHOD FOR MANUFACTURING SEMICONDUCTOR DEVICE

(75) Inventor: Hideaki Yamasaki, Yamanashi (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: Tokyo Electron Limited, Tokyo (JP)

(21) Appl. No.: 11/997,798

(22) PCT Filed: Aug. 9, 2006
(86) PCT No.: PCT/JP2006/315735

§ 371 Date: Feb. 4, 2008

(30) Foreign Application Priority Data
Aug. 10, 2005 (JP) 2005-231547

(51) Int. Cl. H01L 21/28; H01L 21/44

(52) U.S. Cl. 438/585; 438/683; 257/E21.476; 257/E21.158

(57) ABSTRACT

Disclosed is a method for forming a W-based film including a step for placing a substrate in a processing chamber, a step for forming a WSi film by alternately repeating disposition of W through introduction of a W(CO)₆ gas into the processing chamber and silicidation of W or deposition of Si through introduction of an Si-containing gas into the processing chamber, and a step for purging the processing chamber between the supply of the W(CO)₆ gas and the supply of the Si-containing gas.

### FIELD OF THE INVENTION

The present invention relates to a method for forming a W-based film, a method for forming a gate electrode using the film forming method, and a method for manufacturing a semiconductor device.

### BACKGROUND OF THE INVENTION

Conventionally, in a MOS (Metal Oxide Semiconductor) type semiconductor, polysilicon (Poly-Si) has been used for manufacturing a gate electrode, and SiO₂ or SiON is used to form a gate insulating film. However, due to a recent trend for high integration of an LSI (Large Scale IC), the gate insulating film becomes thinner to have a thickness of about 2 nm or less. With this, there has been a problem that direct tunnel leakage current passing through the gate insulating film is increased due to quantum tunneling effect. In order to solve the problem, there is an approach of reducing the gate leakage current by making the thickness of the gate insulating film thick by using high-k material having a dielectric constant higher than that of Si oxide film to form the gate insulating film.

However, when the gate insulating film is formed of Hf-based material as a typical high-k material and combined with the Poly-si gate electrode, there occur an interaction at an interface between the gate insulating film and the gate electrode and a Fermi-level pinning effect that a flat band voltage is shifted.

Moreover, accompanying with a thin-film of the gate insulating film, a depletion layer is generated in an interface between the Poly-Si gate electrode and the gate oxide film formed thereunder, whereby the electrical characteristics are deteriorated when the gate electrode is driven.

Therefore, a metal gate electrode is introduced as a solution for the Fermi-level pinning effect generated by using the high-k material and the gate depletion.

The Poly-Si can form two types of electrodes, i.e., p type and n type electrodes, by an ion implantation after one time of a film formation. However, the metal gate electrode requires a device for forming the metal gate electrode according to respective work functions for p type or n type electrode and two or more chambers need to be prepared. Therefore, it is uneconomical.

Further, a W-based film such as a WSi film or a WN film is considered as the metal gate electrode, and chemical vapor deposition (CVD), which can sufficiently cope with miniaturization of devices, is used as a manufacturing method thereof. Although WF₆ is conventionally used as a W source in the CVD for forming the W-based film, F contained in the WF₆ influences on a film quality of the gate oxide film, so that it may cause a malfunction of the device. Accordingly, tungsten carbonyl (W(CO)₆) gas without including F is considered as the W source (See, e.g., Patent Document 1).

However, in a case of forming the WSi film or the WN film by using W(CO)₆ as the W source, oxygen generated during the W(CO)₆ decomposition is included in the film. Then, the oxygen moves into the high-k film during annealing, so that an equivalent SiO₂ film thickness (EOT) of the high-k film becomes thick. Moreover, if the WSi film or the WN film is formed by the conventional CVD by using a gas containing Si or N in addition to W(CO)₆, surface roughness grows worse, thereby increasing the gate leakage current.

Patent Document 1: Japanese Patent Laid-open Application No. 2004-231995.

### SUMMARY OF THE INVENTION

It is, therefore, a primary object of the present invention to provide a W-based film forming method capable of achieving both work functions for p type and n type, a gate electrode forming method using the W-based film forming method, and a semiconductor device manufacturing method using the gate electrode forming method.

It is another object of the present invention to provide a method for forming a W-based film having controlled composition and distribution, small oxygen concentration and an even surface, a method for forming a gate electrode using the film forming method, and a method for manufacturing a semiconductor device using the gate electrode forming method.

It is still another object of the present invention to provide a computer-readable storage medium storing therein a control program for executing the W-based film forming method.

In accordance with a first aspect of the present invention, there is provided a method for forming a W-based film including: disposing a substrate in a processing chamber; forming a WSi film by alternately repeating deposition of W by introducing W(CO)₆ gas into the processing chamber and silicidation of the W or deposition of Si by introducing a Si-containing gas into the processing chamber; and purging the processing chamber between the supply of the W(CO)₆ gas and the Si-containing gas.

In the first aspect, the deposition of the W by introducing the W(CO)₆ gas, the purge of the processing chamber, the silicidation of the W or the deposition of the Si by the Si-containing gas, and the purge of the processing chamber are preferably repeated twice or more in that order.

Further, the Si-containing gas may be selected from SiH₄, Si₂H₆, TDMAS, and BTBAS, and particularly, it is preferably SiH₄. The purge of the processing chamber may be performed by using a purge gas selected from Ar gas, He gas, N₂ gas, and H₂ gas, and preferably the Ar gas.

Further, Si/W composition of the WSi film is preferably changed by controlling a flow rate of the Si-containing gas and a ratio of a W(CO)₆ gas supplying time and a Si-containing gas supplying time.

Further, the deposition of the W by introducing the W(CO)₆ gas is performed at a temperature equal to or higher than a temperature at which the W(CO)₆ gas is decomposed.

In accordance with a second aspect of the present invention, there is provided a method for forming a gate electrode including: disposing a silicon substrate formed with a gate insulating film thereon in a processing chamber; forming a gate electrode by forming a WSi film on the gate insulating film of the silicon substrate by alternately repeating deposition of W by introducing W(CO)₆ gas into the processing chamber and silicidation of the W or deposition of Si by introducing a Si-containing gas into the processing chamber; and purging the processing chamber between the W(CO)₆ gas supply and the Si-containing gas supply.

In the second aspect, Si/W composition of the WSi film is changed by controlling a flow rate of the Si-containing gas and a ratio of a W(CO)₆ gas supplying time and a Si-containing gas supplying time, whereby a work function can be changed in a range of from n type use to p type use

In accordance with a third aspect of the present invention, a method for manufacturing a semiconductor device including: forming a gate insulating film on a semiconductor substrate; disposing a silicon substrate on which the gate insulating film is formed in a processing chamber; forming a gate electrode by forming a WSi film on the gate insulating film of the silicon substrate by alternately repeating deposition of W by introducing W(CO)₆ gas into the processing chamber and silicidation of the W or deposition of Si by introducing Si-containing gas into the processing chamber; purging the processing chamber between the W(CO)₆ gas supply and the Si-containing gas supply; and forming an impurity diffusion region around the semiconductor substrate.

In accordance with a fourth aspect of the present invention, there is provided a method for forming a W-based film including: disposing a substrate in a processing chamber; forming a WN film by alternately repeating deposition of W by introducing W(CO)₆ gas into the processing chamber and nitridation of W by introducing an N-containing gas into the processing chamber; and purging the processing chamber between the W(CO)₆ gas supply and the N-containing gas supply.

In the fourth aspect, the deposition of the W by introducing the W(CO)₆ gas, the purge of the processing chamber, the nitridation of the W by introducing the N-containing gas, and the purge of the processing chamber are preferably repeated twice or more in that order.

Further, the N-containing gas may be NH₃ gas. The purge of the processing chamber may be performed by using a purge gas selected from Ar gas, He gas, N₂ gas, and H₂ gas, and Ar gas is preferable.

Further, a thickness of the W film formed per every single W deposition by introducing the W(CO)₆ gas is preferably 5 nm or less.

The deposition of the W by introducing the W(CO)₆ gas is preferably performed at a temperature equal to or higher than a temperature at which the W(CO)₆ gas is decomposed.

In accordance with a fifth aspect of the present invention, there is provided a method for forming a gate electrode including: disposing a silicon substrate formed with a gate insulating film thereon is formed in a processing chamber; forming a gate electrode by forming a WN film on the gate insulating film of the silicon substrate by alternately repeating deposition of W by introducing W(CO)₆ gas into the processing chamber and nitridation of W by introducing N-containing gas into the processing chamber; and purging the processing chamber between the supply of the W(CO)₆ gas and N-containing gas.

In accordance with a sixth aspect of the present invention, there is provided a method for manufacturing a semiconductor device including: forming a gate insulating film on a semiconductor substrate; disposing a silicon substrate formed with the gate insulating film thereon in a processing chamber; forming a gate electrode by forming a WN film on the gate insulating film of the silicon substrate by alternately repeating deposition of W by introducing W(CO)₆ gas into the processing chamber and nitridation of the W by introducing N-containing gas into the processing chamber; purging the processing chamber between the supply of the W(CO)₆ gas and the N-containing gas; and forming an impurity diffusion region around the semiconductor substrate.

In accordance with a seventh aspect of the present invention, there is provided a computer readable-storage medium for storing therein a computer-executable control program, wherein the control program controls a film forming apparatus to perform a method for forming a W-based film comprising: disposing a substrate in a processing chamber; forming WSi film by alternately repeating deposition of W by introducing of W(CO)₆ gas into the processing chamber and silicidation of the W or deposition of Si by introducing Si-containing gas into the processing chamber; and purging the processing chamber between the supply of the W(CO)₆ gas and the Si-containing gas.

In accordance with an eighth aspect of the present invention, there is provided a computer readable-storage medium for storing therein a computer-executable control program, wherein the control program controls a film forming apparatus to perform a method for forming a W-based film comprising: disposing a substrate in a processing chamber; forming a WN film by alternately repeating deposition of W by introducing W(CO)₆ gas into the processing chamber and nitridation of the W by introducing N-containing gas into the processing chamber; and purging the processing chamber between the supply of the W(CO)₆ gas and the N-containing gas.

In accordance with the present invention, since the processing chamber is purged between the W(CO)₆ gas supply and the Si-containing gas supply when the WSi film is formed by alternately repeating deposition of W by introducing of the W(CO)₆ gas into the processing chamber and silicidation of the W or deposition of Si by introducing the Si-containing gas into the processing chamber, Si/W composition of the WSi film to be formed can be changed in a wide range. Therefore, it is possible to form the WSi film having a work function in a range of from n type use to p type use, and gate electrodes of nMOS and pMOS can be separately formed in a single chamber by applying the film forming method to form the gate electrode. Moreover, since the purging performed between the supply of the W(CO)₆ gas and the Si-containing gas prevents oxygen from being received into a film being formed, a WSi film having a small quantity of oxygen can be obtained. Since the W(CO)₆ gas and the Si-containing gas do not exist in the processing chamber simultaneously, abnormal development on the substrate surface caused by reaction between the gases is restricted so that a WSi film of a very even surface can be obtained. Due to this, when applying the obtained film to a gate electrode, it is possible to prevent the equivalent SiO₂ film thickness (EOT) caused by the oxygen diffusion into the gate insulating film from being thick. Further, it is also possible to restrict a gate leakage current caused by roughness of the gate electrode.

Moreover, since the processing chamber is purged between the supply of the W(CO)₆ gas and the N-containing gas when a WN film is formed by alternately repeating deposition of W by introducing the W(CO)₆ gas into the processing chamber and nitridation of the W by introducing the N-containing gas into the processing chamber, the concentration of N in the thickness direction of the film is uniform and it is possible to prevent oxygen from being received into a film being formed, so that a WN film having a small quantity of oxygen can be obtained. Due to this, when applying the film forming method to a gate electrode, it is possible to prevent the equivalent SiO₂ film oxide thickness (EOT) caused by the oxygen diffusion to the gate insulating film from being thick.

### BRIEF DESCRIPTION OF THE DRAWINGS

FIG. 1 is a cross sectional view schematically illustrating a WSi film forming apparatus for carrying out a method in accordance with a first embodiment of the present invention;

FIG. 2 is a timing diagram illustrating a sequence of the method in accordance with the first embodiment of the present invention;

FIG. 3 is a view illustrating a relationship between a flow rate of SiH₄ and composition (RBS Si/W reduced value) of Si/W of WSi film in accordance with the first embodiment of the present invention;

FIG. 4 is a view illustrating a relationship between composition of Si/W in WSi film and oxygen concentration in the film in accordance with the first embodiment of the present invention;

FIG. 5A is a view illustrating a method for manufacturing a MOS type semiconductor device having a gate electrode formed by the method in accordance with the first embodiment of the present invention;

FIG. 5B is a view illustrating the method for manufacturing the MOS type semiconductor device having the gate electrode formed by the method in accordance with the first embodiment of the present invention;

FIG. 5C is a view illustrating the method for manufacturing the MOS type semiconductor device having the gate electrode formed by the method in accordance with the first embodiment of the present invention;

FIG. 6A is an electron microscope photograph illustrating a surface of the WSi film formed by the method in accordance with the first embodiment of the present invention;

FIG. 6B is an electron microscope photograph illustrating a surface of the WSi film formed in the conventional chemical vapor deposition (CVD);

FIG. 7 is a cross sectional view schematically illustrating a WN film forming apparatus for performing a method in accordance with a second embodiment of the present invention;

FIG. 8 is a timing diagram illustrating a sequence of the method in accordance with the second embodiment of the present invention;

FIG. 9 is a view illustrating a difference between distributions of N concentration in the films formed by NH3 nitridation;

FIG. 10A is a view illustrating a manufacturing method for a MOS type semiconductor device having a gate electrode formed by the method in accordance with the second embodiment of the present invention;

FIG. 10B is a view illustrating a manufacturing method for the MOS type semiconductor device having the gate electrode formed by the method in accordance with the second embodiment of the present invention; and

FIG. 10C is a view illustrating a manufacturing method for the MOS type semiconductor device having the gate electrode formed by the method in accordance with the second embodiment of the present invention.

### DETAILED DESCRIPTION OF THE EMBODIMENTS

Hereinafter, embodiments of the present invention will be described in detail with reference to the accompanying drawings.

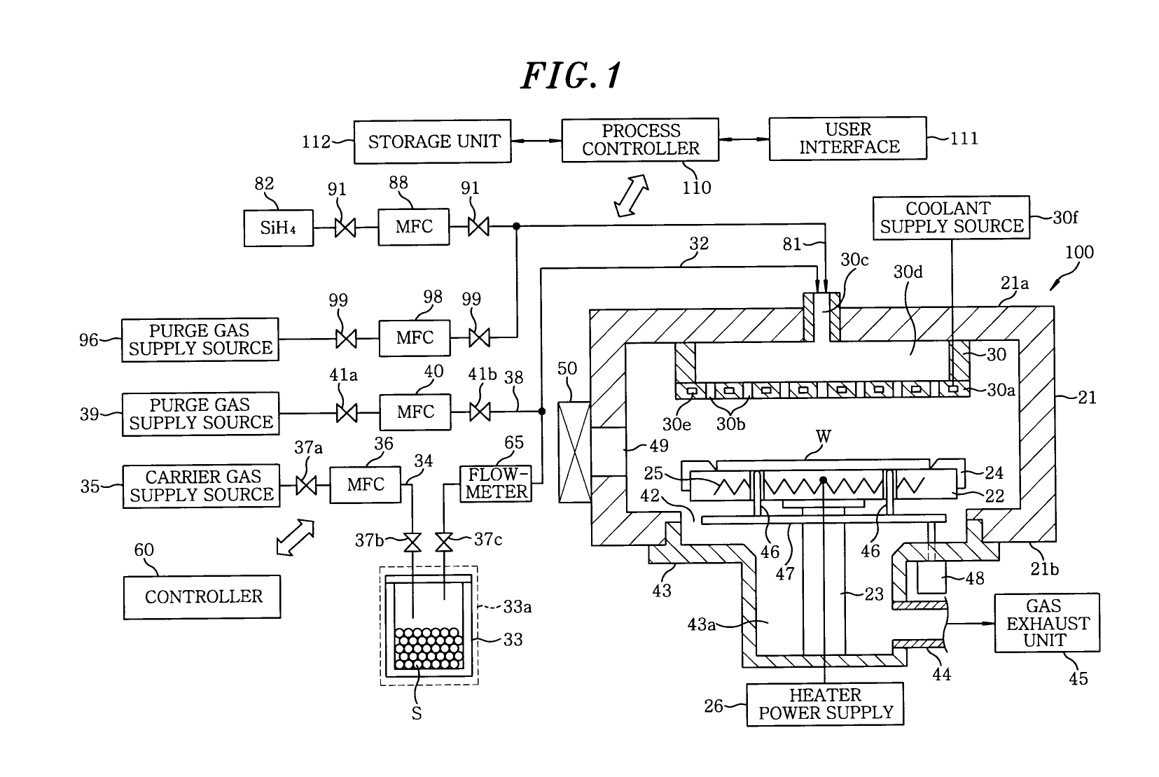

First, a first embodiment of the present invention will be described. FIG. 1 is a cross sectional view schematically illustrating a WSi film forming apparatus 100 for carrying out a method in accordance with the first embodiment of the present invention.

The film forming apparatus 100 includes a substantially cylindrical airtight chamber 21. A circular opening 42 is formed at a substantially central portion of a bottom wall 21b of the chamber 21. Further, a gas exhaust chamber 43 projecting downward is provided on the bottom wall 21b while communicating with the opening 42. A susceptor 22 made of ceramic, e.g., AlN or the like, is provided in the chamber 21 to horizontally support a wafer W as a target object. The susceptor 22 is supported by a cylindrical supporting member 23 extending upward from a central bottom portion of the gas exhaust chamber 43. A guide ring 24 for guiding the wafer W is provided on an outer periphery portion of the susceptor 22. Moreover, a resistance heater 25 is buried in the susceptor 22 to heat the susceptor 22 by a power supplied from a heater power supply 26 and the wafer W is heated by the heat of the susceptor 22. Further, the heat thermally decomposes W(CO)₆ gas introduced in the chamber 22, as described later. A controller (not shown) is connected to the heater power supply 26, thereby controlling an output of the heater 25 according to a signal of a temperature sensor (not shown). Further, a heater (not shown) is buried in a wall of the chamber 21 to heat the wall to a temperature from about 40 to 80° C.

The susceptor 22 is provided with three wafer supporting pins 46 (only two pins shown) for supporting and vertically moving the wafer W. The wafer supporting pins 46 can be protruded from or retracted into the surface of the susceptor 22 and are fixed on a supporting plate 47. Further, the wafer supporting pins 46 are elevated by a driving mechanism 48, such as an air cylinder and the like, via the supporting plate 47.

Provided on a ceiling wall 21a of the chamber 21 is a shower head 30 having a shower plate 30a at the bottom portion thereof. The shower plate 30a includes a plurality of gas injection holes 30b for injecting a gas toward the susceptor 22. A gas inlet opening 30c is disposed in the top wall of the shower head 30 for introducing a gas in the shower head 30. The gas inlet opening 30c is connected to a line 32 for supplying W(CO)₆ gas which is a carbonyl gas, and further connected to a line 81 for supplying a Si-containing gas, e.g., SiH₄ gas. Further, a gas diffusion space 30d is formed in the shower head 30. A coolant path 30e is concentrically provided in the shower plate 30a to prevent the W(CO)₆ gas from being decomposed in the shower head 30. A coolant supply source 30f supplies coolant such as cooling water or the like to the coolant path 30e to control the temperature of the shower head 30 from about 20 to 100° C.

The other end of the line 32 is inserted into a W source container 33 in which solid tungsten carbonyl (W(CO)₆) S is included. A heater 33a as a heating device is provided around the W source container 33. A carrier gas line 34 is inserted into the W source container 33 and Ar gas as a carrier gas is supplied into the W source container 33 via the carrier gas line 34 from a carrier gas supply source 35 and the solid (W(CO)₆)S in the W source container 33 is vaporized into W(CO)₆ gas due to a heat of the heater 33a. The W(CO)₆ gas is carried by the carrier gas and is supplied into the diffusion space 30d in the chamber 21 via the line 32. Provided in the carrier gas line 34 are a mass flow controller 36, and valves 37a and 37b installed respectively at the upstream side and the downstream side of the mass flow controller 36. Further, a flowmeter 65 and a valve 37c are provided to measure a flow rate based on the quantity of the W(CO)₆ gas. Heaters (not shown) are provided around the lines 32 and 34 and control the lines 32 and 34 at a temperature, e.g., from about 20 to 100° C., preferably from about 25 to 60° C. to prevent solidification of the W(CO)₆ gas.

One end of a purge gas line 38 is connected with the line 32 and the other end thereof is connected with a purge gas supply source 39. The purge gas supply source 39 is configured to supply a purge gas, e.g., H₂ gas or an inactive gas such as Ar gas, He gas, N₂ gas and the like. Exhausting of a remaining film forming gas in the line 32 and purging of the chamber 21 are performed by the purge gas. In the purge gas line 38, a mass flow controller 40, and valves 41a and 41b installed at downstream and upstream sides of thereof are provided.

Further, one end of a line 81 is connected with a Si-containing gas supply source 82 to supply a Si-containing gas such as SiH₄ gas. The line 81 is provided with a mass flow controller 88, and valves 91 installed at downstream and upstream sides thereof.

Further, a purge gas line 97 is connected with the line 81, and one end of the purge gas line 97 is connected with a purge gas supply source 96. The purge gas supply source 96 supplies H₂ gas or an inactive gas such as Ar gas, He gas, and N₂ gas as a purge gas. Exhausting of a remaining film forming gas in the line 81 and purging of the chamber 21 are performed by the purge gas. The purge gas line 97 is provided with a mass flow controller 98, and valves 99 installed at downstream and upstream sides thereof.

The respective mass flow controllers and valves, and flowmeters 65 are controlled by a controller 60 so that start and stop of the supply of the carrier gas, W(CO)₆ gas, SiH₄ gas, and the purge gas are controlled and flow rates of the gases are controlled to predetermined flow rates. The flow rate of W(CO)₆ gas to be supplied into the gas diffusion space 30d in the chamber 21 is controlled by controlling the flow rate of the carrier gas with the mass flow controller 36 based on the value of the flowmeter 65.

A gas exhaust line 44 is connected to a side surface of the gas exhaust chamber 43, and a gas exhaust unit 45 including a high speed vacuum pump is connected with the gas exhaust line 44. By operating the gas exhaust unit 45, a gas in the chamber 21 is uniformly discharged into a space 43a of the gas exhaust chamber 43 and then is exhausted through the gas exhaust line 44. Accordingly, the inner space of the chamber 21 can be depressurized to a predetermined vacuum level.

Provided on the sidewall of the chamber 21 are a loading/unloading port 49 for loading/unloading the wafer W between the chamber 21 and a transfer chamber (not shown) adjacent to the film forming apparatus 100 and a gate valve 50 for opening and closing the loading/unloading port 49.

Each component of the film forming apparatus 100 is connected with a process controller 110. Further, the process controller 110 controls the valves and the like via the controller 60. The process controller 110 is connected with a user interface 111 having a keyboard, a display and the like. A process operator uses the keyboard when inputting commands for managing the film forming apparatus 100, and the display is used to display the operation status of the film forming apparatus 100.

Further, the process controller 110 is connected with a storage unit 112 for storing therein control programs for implementing various processes in the film forming apparatus 100 under the control of the process controller 110, and programs, i.e., recipes, to be used in operating each component of the film forming apparatus 100 to carry out processes in accordance with processing conditions. The recipes can be stored in a hard disk or a semiconductor memory, or can be set at a certain position of the storage unit 112 while being recorded on a portable storage medium such as a CDROM, a DVD and the like.

If necessary, the process controller 110 executes a recipe read from the storage unit 112 in response to instructions from the user interface 111, thereby implementing a required process in the film forming apparatus 100 under the control of the process controller 110.

Next, the film forming method using the film forming apparatus 100 in accordance with the embodiment of the present invention will be described.

First, the gate valve 50 is opened and a wafer W formed with a gate insulating film thereon is introduced into the chamber 21 from the loading/unloading port 49 to be loaded on the susceptor 22. The susceptor 22 is already heated by the heater 25, the wafer W is heated by the heat of the susceptor 22. The chamber 21 is exhausted to vacuum by the vacuum pump of the gas exhaust unit 45, so that the pressure of the chamber 21 is maintained at 6.7 Pa or less. A heating temperature of the wafer W is preferably in a range of from 100 to 600° C.

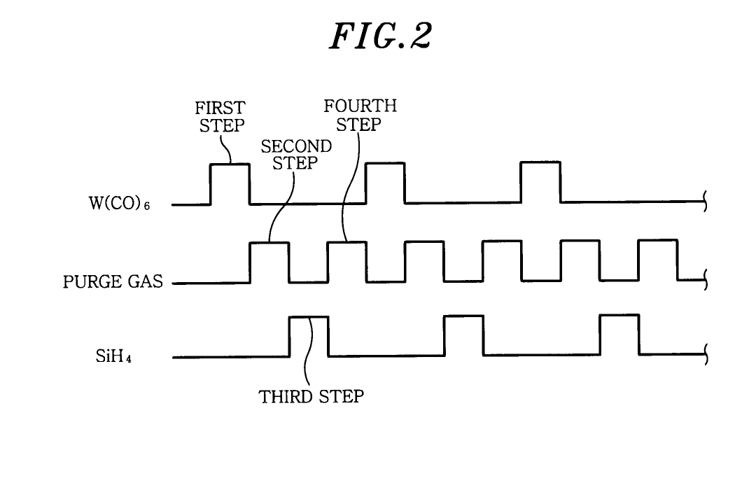

Then, as illustrated in FIG. 2, the film formation is performed by alternate gas flows. That is, the following first to fourth steps are repeated predetermined times.

First, the valves 37a and 37b are opened and a carrier gas, e.g., Ar gas is supplied into the W source container 33, in which a solid W(CO)₆ material S is accommodated, from the carrier gas supply source 35; the W(CO)₆ material S is heated by the heater 33a to be vaporized; and the valve 37c is opened to carry W(CO)₆ gas generated by the carrier gas. Then, the W(CO)₆ gas is introduced into the chamber 21 via the line 32 and the shower head 30 and is supplied on the wafer W to form a ultra-thin W film (first step). At this time, a purge gas as a dilution gas such as Ar gas is simultaneously supplied from the purge gas supply source 39. During the film formation, the W(CO)₆ gas is decomposed so that W only is deposited on the wafer and CO gas, a decomposed product, is exhausted. Moreover, the carrier gas and the purge gas are not limited to Ar gas but other gases such as N₂ gas, H₂ gas, He gas and the like may be used.

In the first step, a flow rate of the carrier gas is preferably in a range of from 10 to 500 mL/min (sccm) in a case of using Ar gas as the carrier gas, and a flow rate of the dilution gas is preferably in a range of from 10 to 1,500 mL/min (sccm) in a case of using Ar gas as the dilution gas. In detail, (Ar as the carrier gas)/(Ar as the dilution gas)=60/340 mL/min (sccm). Moreover, required time for this step is preferably in a range of from 1 to 60 seconds, specifically, 5 seconds.

Subsequently, the valves 37a to 37c are closed to stop the supply of the W(CO)₆ gas. Accordingly, the purge gas only is supplied so that the CO gas produced by the decomposition is exhausted out of the chamber 21 (second step). If CO remains in the chamber, it is included in the film, whereby oxygen in the film increases. However, it is difficult for the film to receive CO by purging of the chamber 21 by the purge gas. In this case, it is preferred that the CO gas is rapidly exhausted by high speed exhaustion. In the second step, the flow rate of the purge gas is preferably in a range of from 10 to 2,000 mL/min (sccm) when using Ar gas, specifically, 400 mL/min. Required time for the second step is preferably in a range of from 1 to 60 seconds, specifically, 10 seconds.

Next, the valves 41a and 41b are closed to stop the supply of the purge gas from the purge gas supply source 39, and the valves 91 and 99 are opened to respectively introduce Si-containing gas, e.g., SiH₄ gas and a purge gas as a dilution gas, e.g., Ar gas from the Si-containing gas supply source 82 and the purge gas supply source 96 into the chamber 21 via the line 81 and the shower head 30. With this, the ultra-thin W film that is formed before is silicided or an ultra-thin Si film is deposited on the W film (third step). As the Si-containing gas, a gas which does not contain oxygen and is decomposed into Si may be used, and Si₂H₆ may be exemplified other than SiH₄. Further, an organic-based gas may be also used, and TDMAS (tris(dimethylamino)silane) presented by the flowing chemical formula (1) or BTBAS (bis(tertiary-butylamino)silane) presented by (2) by the following chemical formula (2) may be used.

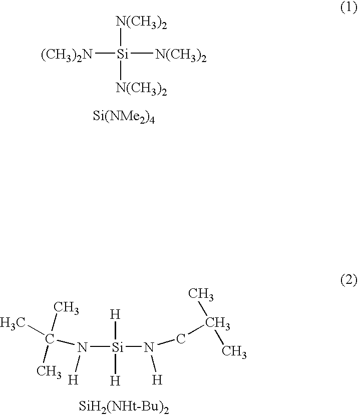

In the third step, the flow rate of SiH₄ gas used as the Si-containing gas is preferably in a range of from 10 to 1,000 mL/min (sccm). Further, the flow rate of Ar gas used as the dilution gas is preferably in a range of from 10 to 1,000 mL/min (sccm). In this step, Si percentage in the WSi film to be finally formed can be controlled by adjusting the flow rate of the Si-containing gas and/or a time ratio of this step and the first step. Required time for the third step is preferably in a range of from about 1 to 60 seconds, specifically, 5 seconds.

Next, the valve 91 is closed to stop the supply of the Si-containing gas, so that the purge gas only is supplied to purge the inside of the chamber 21 (fourth step). In the fourth step, the flow rate of the Ar gas used as the purge gas is preferably in a range from about 10 to 2,000 mL/min (sccm), specifically, 400 mL/min (sccm). Further, required time for the fourth step is preferably 1 second to 60 seconds, particularly, 10 seconds.

By repeating the first to fourth steps predetermined times, WSi film of a desired thickness and desired composition can be obtained.

In the first to fourth steps, a temperature of the wafer W is preferably in a range of from 250 to 600° C. A pressure in the chamber 21 is preferably in a range from about 5 to 1,330 Pa. In a view of introducing Si, it is preferable that the pressure in the chamber 21 is set to be high. The pressure in the chamber 21 is, e.g., 133 Pa. The temperature of the wafer W and the pressure in the chamber 21 may be changed depending on the steps.

When a W source and a Si source are currently supplied during a manufacture of the gate electrode of the WSi film, it is difficult to introduce a large quantity of Si into the WSi film. However, in the embodiment of the present invention, the flow rate of the Si-containing gas can be changed by alternately introducing gases, and/or the composition ratio of Si/W in the film can be largely changed in a range of from 1.3 to 4.6 measured by RBS (Rutherford Backscattering Spectroscopy) by changing the time ratio of the third step and the first step. Therefore, a work function can be changed in a range of from n type use to p type use, so that the gate electrode can be manufactured as an nMOS gate electrode or as a pMOS gate electrode depending on the composition ratio of Si/W in the film. Particularly, in a case of the nMOS, the work function of the gate electrode is approximately 4.4 eV or less and this work function can be obtained by the composition ratio of Si/W in a range of from 3 to 5. Further, in a case of pMOS, the work function of the gate electrode is approximately 4.8 eV or greater, and this work function can be obtained by the composition ratio of Si/W in a range of from 0.1 to 2.5.

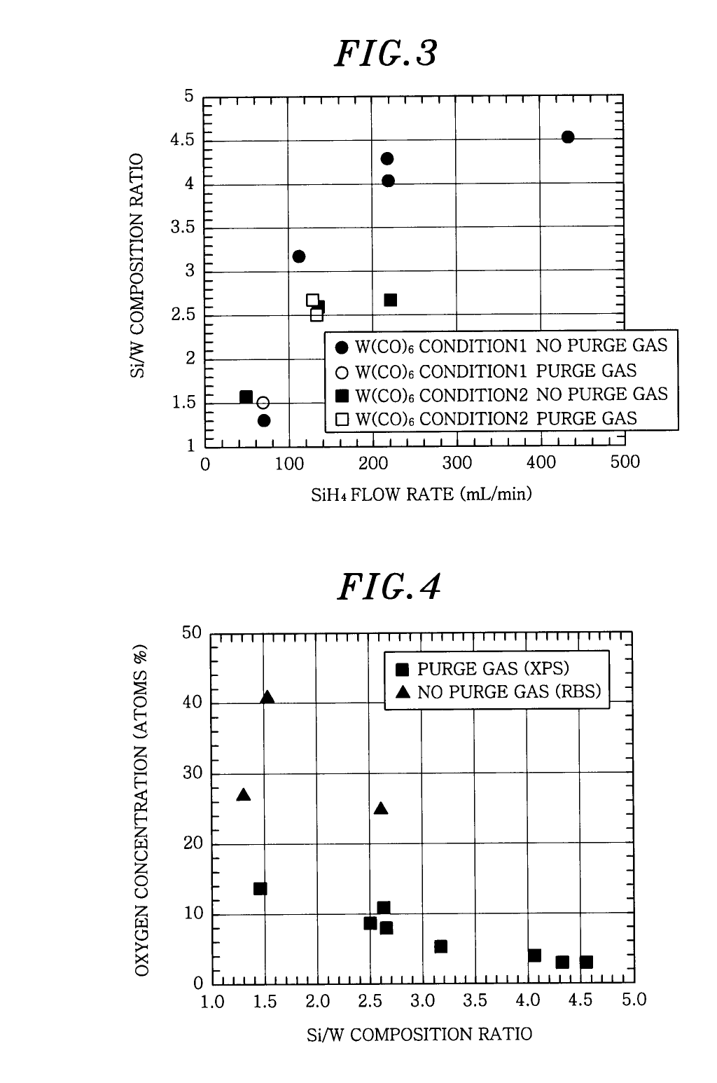

FIG. 3 is a view illustrating a relationship between the flow rate of the SiH₄ gas and the composition ratio of Si/W in the film. Although the composition ratio is usually measured by RBS, the composition ratio of Si/W is converted by considering a sputter rate of Si and W according to the composition ratio of Si/W measured by XPS (X-ray Photoelectron Spectroscopy). As illustrated in the drawing, it was confirmed that the composition ratio of Si/W increases as the flow rate of the SiH₄ gas increases. The increase is more outstanding under a condition 1 of a small flow rate of W(CO)₆ than under a condition 2 of a large flow rate of W(CO)₆. Moreover, it was confirmed that an existence of the purge gas does not influence the composition ratio of Si/W. Further, from the drawing, it was confirmed that the composition ration of Si/W can be set in a range of from 1.3 to 4.5 by changing the flow rate of SiH₄ gas from 40 mL/min (sccm) to 440 mL/min (sccm).

As such, since the work function can be changed in a range of from n type use to p type use by only changing the concentration of Si in the film, a metal gate electrode having p type or n type use work function can be formed in a single chamber.

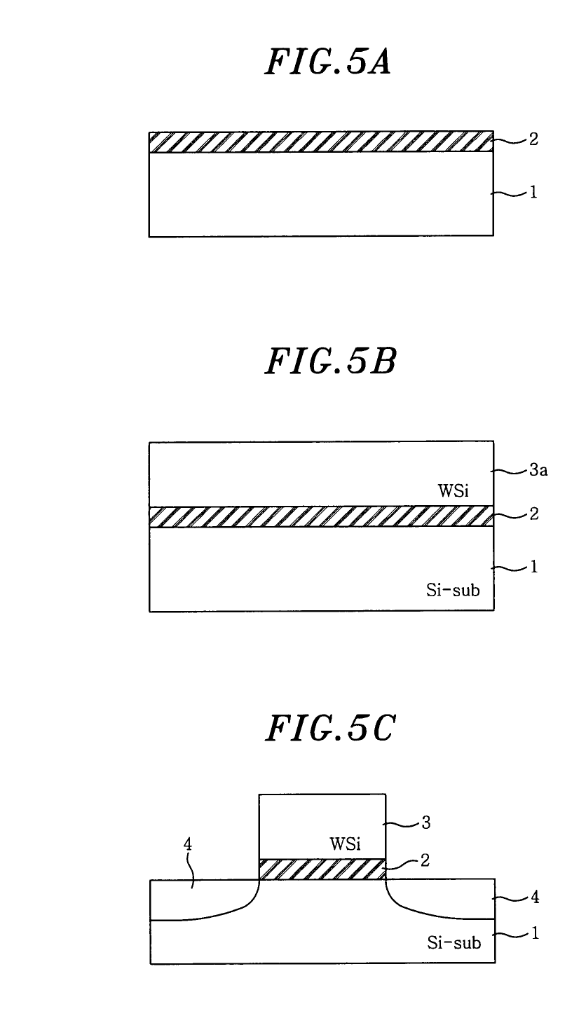

Moreover, since the pressure in the chamber 21 is relatively high, if the purge of the second step is not performed, CO is not sufficiently discharged when the composition of Si/W is 2.5 or less, whereby oxygen in the film increases to several tens % (atoms %). However, since CO can be rapidly discharged in the second step, oxygen in the film can be reduced to a level lower than 10%. This is illustrated in FIG. 4. FIG. 4 shows a relationship between the composition ratio of Si/W and oxygen concentration in the film. In the drawing, the square symbol indicates the case where purging is performed in the second step and a quantity of oxygen is measured by XPS. The triangle symbol indicates the case where no purging is performed in the second step and a quantity of oxygen is measured by RBS. The measurement results are slightly different depending on the methods of measuring oxygen, and the value measured by the XPS tends to be higher than that measured by the RBS. As is obvious by referring to the drawing, the oxygen in the film decreases as the composition ratio of Si/W increases, i.e., as Si becomes rich. Further, the quantity of oxygen is about 5% or less when the composition ratio of Si/W is greater than 3. On the contrary, it was confirmed that, although the quantity of oxygen in the film is relatively high when the composition ratio of Si/W is less then 3, the quantity of oxygen is reduced in the case of the purging less than half of that in the case of no purging.

The alternate film formation is similar to an ALD (Atomic Layer Deposition) but is different from that in view of the following points. In ALD, source gas is adsorbed on a substrate chemically or physically. A molecular layer of the adsorbed gas reacts with a next gas to develop one to few atomic layers and this process is repeated to obtain a desired film thickness. On the other had, in the embodiment of the present invention, the source gas is decomposed on the substrate to form a film. Then, the surface of the film is silicided with the Si-containing gas such as SiH₄ and the like to form an ultra-thin silicide and this process is repeated to form a desired film thickness. In this case, when the source gas is W(CO)₆ gas, the temperature for the process needs to be equal to or higher than the temperature appropriate for decomposing the W(CO)₆ gas into single elements and forming the film, and it was confirmed that the temperature is about 300° C. through a film formation experiment using W(CO)₆ gas only.

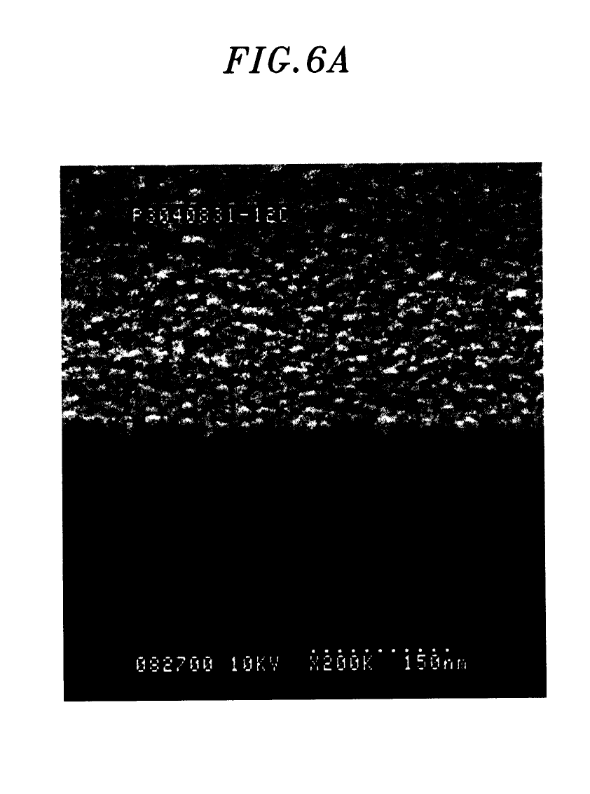

Next, a method for manufacturing a MOS type semiconductor device employing the WSi film formed by the above-described method as a gate electrode will be described briefly with reference to FIGS. 5A to 5C. First, as illustrated in FIG. 5A, a gate insulating film 2 is formed on a Si substrate 1 used as a semiconductor substrate. Next, as illustrated in FIG. 5B, WSi film 3a is formed on the gate insulating film 2 by the alternate film formation as described above. Then, the WSi film 3a is etched to form a gate electrode 3 through a heat treatment, and an impurity diffusion region 4 is formed by ion implantation, so that the MOS type semiconductor device is manufactured as illustrated in FIG. 5C. Thicknesses of the gate insulating film 2 and the gate electrode 3 are, e.g., in a range of from 0.8 to 5 nm and in a range of from 5 to 100 nm, respectively.

Next, specific examples of manufacturing the gate electrode by using the WSi film in accordance with the embodiment will be described.

### Example 1

In the apparatus shown in FIG. 1, the susceptor 22 was heated to 672° C. in advance, and a wafer W having a diameter of 300 mm was loaded on the susceptor 22 by a transfer device. Then, Ar gas as the carrier gas and Ar gas as the dilution gas were supplied in a ratio of (carrier gas Ar)/(dilution gas Ar)=60/340 mL/min (sccm) so that W(CO)₆ gas was introduced into the chamber 21 for 5 seconds, whereby an ultra-thin W film was formed on the wafer W (first step).

Then, as the purge gas, Ar gas of a flow rate 400 mL/min (sccm) was introduced into the chamber 21 for 10 seconds and the inside of the chamber 21 was purged (second step).

Next, SiH₄ gas and Ar gas as the dilution gas were supplied in a ratio of SiH₄/(dilution gas Ar)=100/300 mL/min (sccm), the SiH₄ gas was introduced into the chamber 21 for 5 seconds, so that an ultra-thin Si film was formed on the W film formed in the first step (third step).

Then, as the purge gas, Ar gas of a flow rate of 400 mL/min (sccm) was introduced into the chamber 21 for 10 seconds and the inside of the chamber 21 was purged (fourth step).

The WSi film was obtained by repeating the first to fourth steps 21 times while keeping the pressure in the chamber 21 at 133 Pa. With respect to the WSi film, a sheet resistance was measured by a four edge measuring method and the film thickness was measured by XRF (X-Ray Fluorescence), so that resistivity was estimated therefrom. As a result, the sheet resistance was about 997 Ω/sq, the film thickness was 46.9 nm, and the resistivity was 4,677 μΩ·cm. The Si/W composition ratio of the film measured by the RBS was about 4. By using the WSi film, gate electrodes were formed on SiO₂ films of which thickness was respectively 2 nm, 5 nm and 9 nm, and the work function of the gate electrodes was measured. The measured work function was 4.2 eV and it was confirmed that the formed gate electrodes could serve as gate electrodes of nMOS.

### Example 2

In the apparatus shown in FIG. 1, the susceptor 22 was heated to 672° C. in advance, and a wafer W having a diameter of 300 mm was loaded on the susceptor 22 by the transfer device. Then, Ar gas as the carrier gas and Ar gas as the dilution gas were supplied in a ratio of (carrier gas Ar)/(dilution gas Ar)=60/340 mL/min (sccm), so that W(CO)₆ gas was introduced into the chamber 21 for 10 seconds, whereby an ultra-thin W film was formed on the wafer W (first step).

Next, Ar gas as the purge gas of a flow rate about 400 mL/min (sccm) was introduced into the chamber 21 for 10 seconds and the inside of the chamber 21 was purged (second step).

Next, SiH₄ gas and Ar gas as the dilution gas were supplied in a ratio of SiH₄/(dilution gas Ar)=100/300 mL/min (sccm), so that the SiH₄ gas was introduced into the chamber 21 for 1 second, whereby an ultra-thin Si film was formed on the W film formed at the first step (third step).

Then, as the purge gas, Ar gas of a flow rate 400 mL/min (sccm) was introduced into the chamber 21 for 10 seconds and the inside of the chamber 21 was purged (fourth step).

The WSi film was obtained by repeating the first to fourth steps 21 times while keeping the pressure in the chamber 21 at 133 Pa. With respect to the WSi film, the sheet resistance was measured by the four edge measuring method and the film thickness was measured by XRF, whereby the resistivity was estimated therefrom. As a result, the sheet resistance was 147 Ω/sq, the film thickness was 149.9 nm, and the resistivity was 2,204 μΩ·cm. The Si/W composition ratio of the film measured by RBS was about 1.47. By using the WSi film, gate electrodes were formed on SiO2 films of which thickness was respectively 2 nm, 5 nm and 9 nm, and the work function of the gate electrodes was measured. The measured work function was 4.9 eV and it was confirmed that the formed gate electrodes can serve as gate electrodes of pMOS.

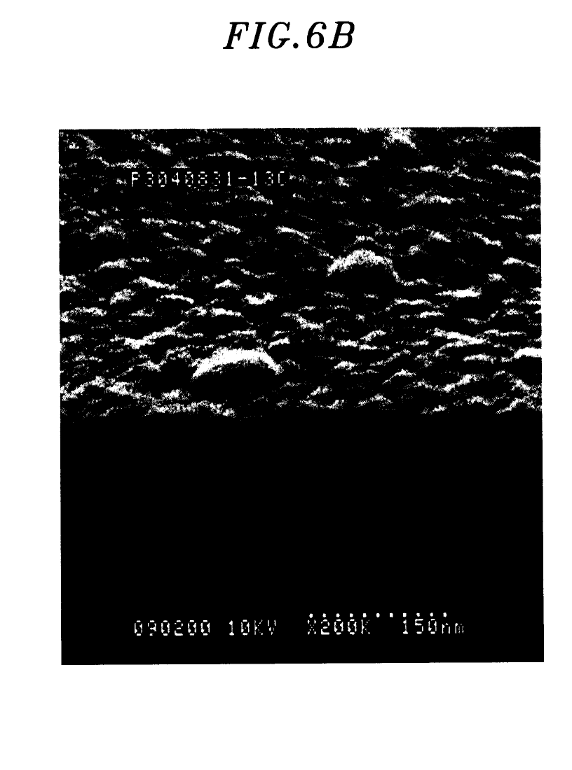

Next, with respect to a case where a film is formed by alternately supplying the W(CO)₆ gas and SiH₄ gas were alternately supplied with the purging interposed therebetween in accordance with the embodiment of the present invention and a case where a film is formed by simultaneously supplying the W(CO)₆ gas and SiH₄ gas in accordance with a conventional CVD, the status and characteristics of the film surfaces of the two cases were examined. First, the surface status was examined by an electron microscope photograph. As a result, it was confirmed that the surface of the film obtained by alternately supplying the gases was fine as illustrated in FIG. 6A. On the contrary, the surface of the film obtained by the conventional CVD was poor. In view of Haze as an index of the surface status, it was confirmed that the Haze was fine with a value 1.21 ppm in the case of the film obtained by the alternate gas supply, while the Haze was significantly poor with a value of 106.0 ppm in the case of the film obtained by the conventional CVD. The central resistivity was 595 μΩ·cm in the case of the film obtained by the alternate gas supply, while 85,452 μΩ·cm in the case of the film obtained by the conventional CVD, whereby it was confirmed that there was a difference greater than 100 times between the two cases.

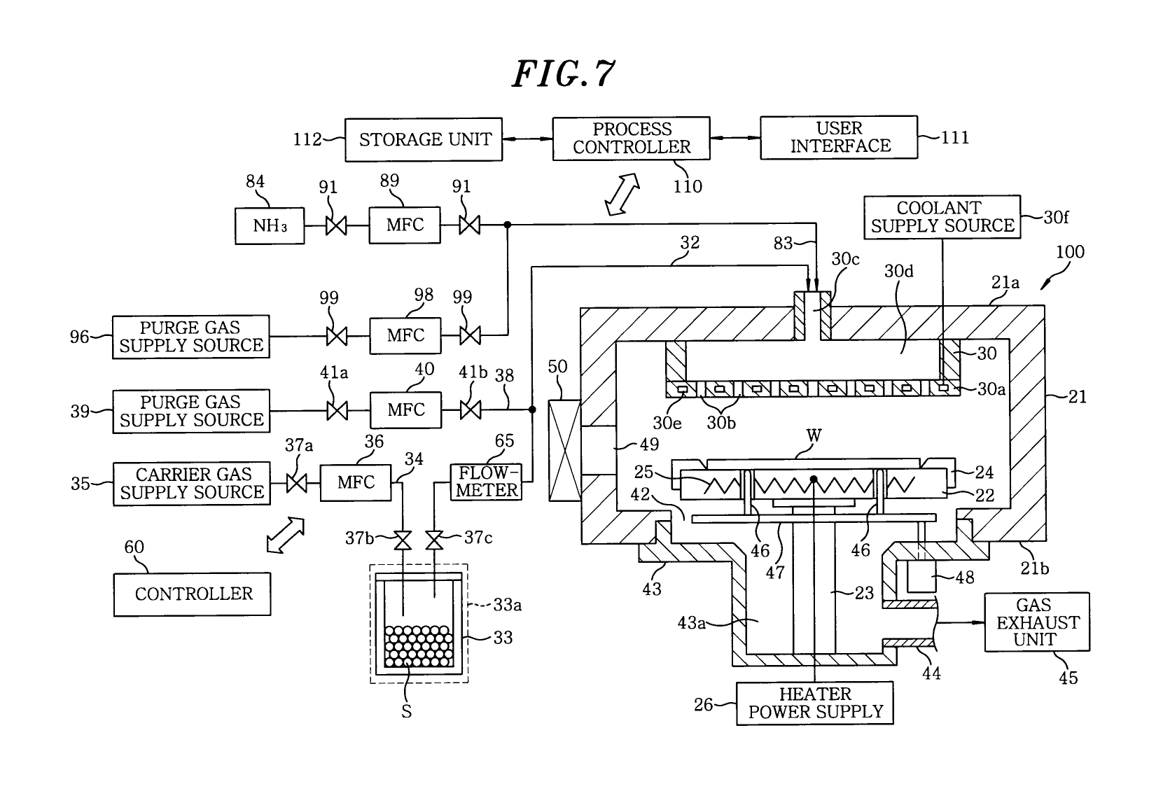

Next, a second embodiment of the present invention will be described. FIG. 7 is a cross sectional view schematically illustrating a WN film forming apparatus 100 for performing a method in accordance with the second embodiment of the present invention. In this embodiment, a gate electrode of the WN film is formed by using NH₃ gas, i.e., N-containing gas instead of the Si-containing gas in the first embodiment. The apparatus in FIG. 7 is identical to the apparatus of FIG. 1, except for an NH₃ gas supply source 84 for supplying NH₃ gas instead of the Si-containing gas (SiH₄) supply source 82 of the apparatus in FIG. 1. In the flowing description, like reference numerals are assigned to the like part as those of FIG. 1, and redundant description thereof will be omitted.

A line 83 is connected with the NH₃ gas supply source 84 and supplies the N-containing gas into the shower head 30. Provided in the line 83 are a mass flow controller 89, and valves 91 installed at the downstream side and the upstream side of the mass flow controller 89.

Next, a film forming method using the film forming apparatus will be described. First, the gate valve 50 is opened and a wafer W formed with a gate insulating film thereon is introduced into the chamber 21 through the loading/unloading port 49 to be loaded on the susceptor 22. The susceptor 22 is already heated by the heater 25, the wafer W is heated by the heat of the susceptor 22. The chamber 21 is exhausted to vacuum by the vacuum pump of the gas exhaust unit 45, so that the pressure in the chamber 21 is maintained at 6.7 Pa or less. A heating temperature of the wafer W is preferably in a range of from 100 to 600° C.

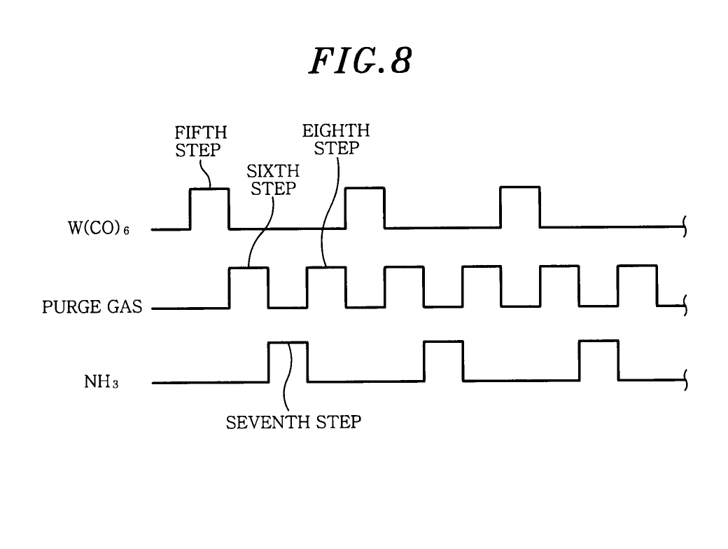

Then, as illustrated in FIG. 8, the film formation is performed by alternate gas flows. That is, the following fifth to eighth steps are repeated predetermined times.

First, the valves 37a and 37b are opened and a carrier gas, e.g., Ar gas is supplied into the W source container 33, in which a solid W(CO)₆ material S is accommodated, from the carrier gas supply source 35; the W(CO)₆ material S is heated by the heater 33a to be vaporized; and the valve 37c is opened to carry W(CO)₆ gas generated by the carrier gas. Then, the W(CO)₆ gas is introduced into the chamber 21 via the line 32 and the shower head 30 and is supplied on the wafer W to form a ultra-thin W film (fifth step). At this time, a purge gas as a dilution gas such as Ar gas is simultaneously supplied from the purge gas supply source 39. During the film formation, the W(CO)₆ gas is decomposed so that W only is deposited on the wafer and CO gas, decomposed product, is exhausted. Moreover, the carrier gas and the purge gas are not limited to Ar gas but other gases such as N₂ gas, H₂ gas, He gas and the like may be used.

In the fifth step, a flow rate of the carrier gas is preferably in a range of from 10 to 500 mL/min (sccm) in a case of using Ar gas as the carrier gas, and a flow rate of the dilution gas is preferably in a range of from 10 to 1,500 mL/min (sccm) in a case of using Ar gas as the dilution gas. In detail, (Ar as the carrier gas)/(Ar as the dilution gas)=60/300 mL/min (sccm). Moreover, required time for this step is preferably in a range of from 1 to 60 seconds, specifically, 5 seconds.

Subsequently, the valves 37a to 37c are closed to stop the supply of the W(CO)₆ gas. Accordingly, the purge gas only is supplied so that the CO gas generated by decomposition is exhausted out of the chamber 21 (sixth step). In this case, it is preferred that the CO gas is rapidly exhausted by high speed exhaustion. In the second step, the flow rate of the purge gas is preferably in a range of from 10 to 2,000 mL/min (sccm) when using Ar gas, specifically, 360 mL/min. Required time for the sixth step is preferably in a range of from 1 to 60 seconds, specifically, 10 seconds.

Next, the valves 41a and 41b are closed to stop the supply of the purge gas from the purge gas supply source 39, and the valves 91 and 99 are opened to respectively introduce NH₃ gas and a purge gas as a dilution gas, e.g., Ar gas from the NH₃ gas supply source 84 and the purge gas supply source 96 into the chamber 21 via the line 83 and the shower head 30. With this, the ultra-thin W film that is formed before is nitrided (seventh step). In the seventh step, the flow rate of NH₃ gas is preferably in a range of from 10 to 1,000 mL/min (sccm). Further, the flow rate of Ar gas used as the dilution gas is preferably in a range of from 10 to 1,000 mL/min (sccm). Specifically, NH₃ gas/(dilution gas Ar) is 310/50 mL/min (sccm). Required time for the seventh step is preferably in a range of from about 1 to 60 seconds, specifically, 5 seconds.

Next, the valve 91 is closed to stop the supply of the NH₃ gas and the purge gas only is supplied to purge the inside of the chamber 21 (eighth step). In the eighth step, the flow rate of the Ar gas used as the purge gas is preferably in a range from about 10 to 2,000 mL/min (sccm), specifically, 360 mL/min (sccm). Further, required time for the eighth step is preferably 1 second to 60 seconds, particularly, 10 seconds.

By repeating the fifth to eighth steps predetermined times, a WN film of a desired thickness and desired composition can be obtained. In the fifth to eighth steps, a temperature of the wafer W is preferably in a range of from 250 to 600° C. A pressure in the chamber 21 is preferably in a range from about 5 to 667 Pa. The temperature of the wafer W and the pressure in the chamber 21 may be changed depending on the steps.

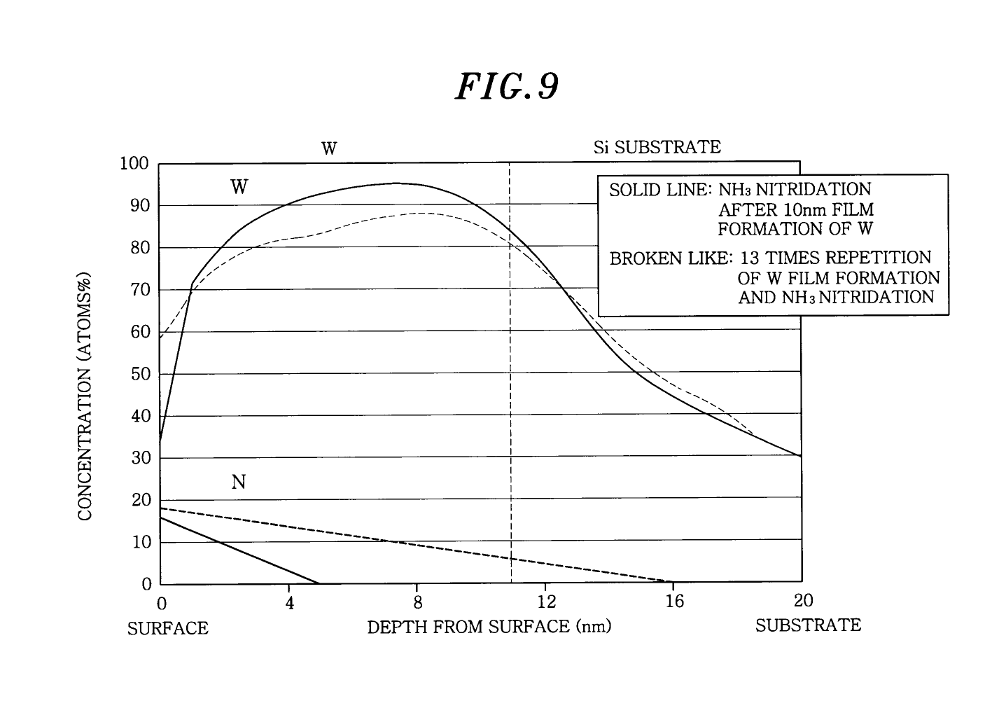

According to investigation by the present inventors, when W(CO)₆ gas and NH₃ gas were used to form the WN film, it was confirmed that the quantity of oxygen in the film increased by simultaneously supplying the gases. Thus, as a way of restricting the quantity of oxygen in the film, the inventors have found that the quantity of oxygen is restricted to form a WN film appropriate for the gate electrode by alternately supplying W(CO)₆ gas and NH₃ gas and interposing the purging between the supplies of the W(CO)₆ gas and NH₃ gas. Moreover, the outermost film only is nitrided when simultaneously supplying W(CO)₆ gas and NH₃ gas. However, it is possible to nitride overall film by the alternate film formation in accordance with the embodiment of the present invention and making the thickness of the W film to be 5 nm or less per every W film formation. This will be described with reference to FIG. 9. In FIG. 9, a horizontal axis is a depth (nm) from the surface of the W film and a vertical axis is concentration of the W and N (atoms %) to present the results of examining depths of existing N from the surfaces of the W films. A solid line indicates a case of NH₃ nitridation performed for 60 seconds after forming the W film of 10 nm on the Si substrate, and a dotted line indicates a case in which a film has a total thickness of 10 nm (corresponding to 0.76 nm per one film formation) by repeating 13 times the deposition of an ultra-thin W film on the Si substrate and NH₃ nitridation. As illustrated in the drawing, when the nitridation is performed after forming the W film, nitrogen enters merely 5 nm from the surface. However, it is possible to introduce N into the entire film by alternately and repeatedly supplying the W(CO)₆ gas and NH₃ gas.

The WN film obtained by the above-mentioned method can be applied to form a metal gate electrode having a work function in a range of 4.6 eV to 5.1 eV.

Even in this embodiment, like the first embodiment, the source gas is decomposed over the substrate during the film formation, the surface is nitrided by using the NH₃ gas to form the ultra-thin nitride. By repeating this process, a predetermined film thickness is obtained. Thus, this process is different from the ALD, and needs a temperature equal to or higher than 300° C. appropriate for decomposing W(CO)₆ gas and forming a film.

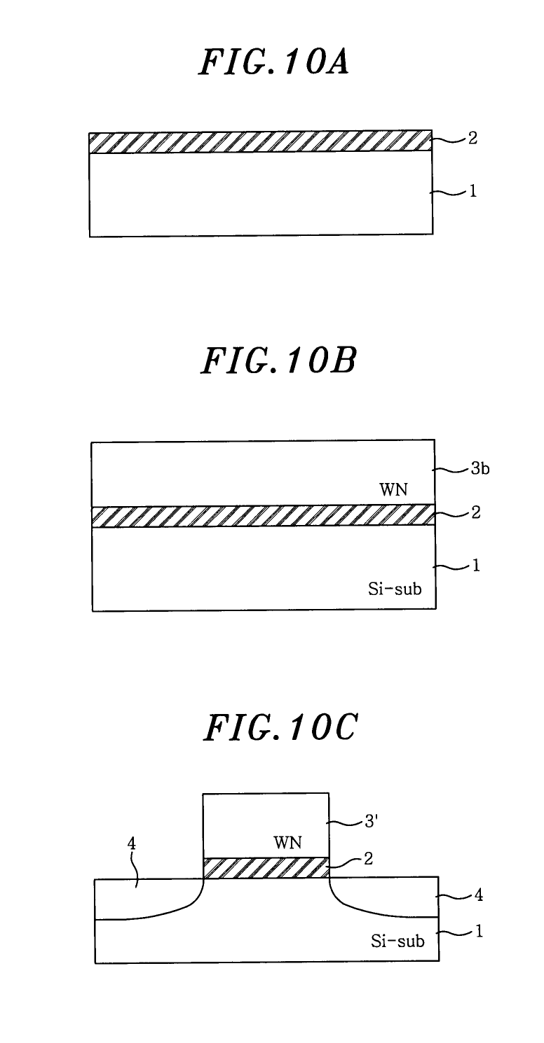

Next, a method for manufacturing a MOS device employing the WN film formed by the above-described method as a gate electrode will be described briefly with reference to FIGS. 10A to 10C. First, as illustrated in FIG. 10A, a gate insulating film 2 is formed on a Si substrate 1 used as a semiconductor substrate. Then, as illustrated in FIG. 10B, a WN film 3b is formed on the gate insulating film 2 by the alternate film formation as described above. Subsequently, the WN film 3b is etched to form the gate electrode 3′ through a heat treatment, and an impurity diffusion region 4 is formed by ion implantation, so that a MOS type semiconductor is manufactured as illustrated in FIG. 10C. Thicknesses of the gate insulating film 2 and the gate electrode 3′ are, e.g., 0.8 to 5 nm and 5 to 100 nm, respectively.

Next, specific examples for manufacturing a gate electrode by using the WN film in accordance with the embodiment of the present invention will be described.

### Example 3

In the apparatus shown in FIG. 7, the susceptor 22 was heated to 672° C. in advance, and a wafer W having a diameter of 300 mm was loaded on the susceptor 22 by a transfer device. Then, Ar gas as the carrier gas and Ar gas as the dilution gas were supplied in a ratio of (carrier gas Ar)/(dilution gas Ar)=60/300 mL/min (sccm), and W(CO)₆ gas was introduced into the chamber 21 for 5 seconds, whereby an ultra-thin W film was formed on the wafer W (fifth step).

Then, as the purge gas, Ar gas of a flow rate 360 mL/min (sccm) was introduced into the chamber 21 for 10 seconds and the inside of the chamber 21 was purged (sixth step).

Next, NH₃ gas and Ar gas as the dilution gas were supplied in a ratio of NH₃/(dilution gas Ar)=310/50 mL/min (sccm), the NH₃ gas was introduced into the chamber 21 for 5 seconds, and the W film formed in the fifth step was nitrided, thereby forming a WN film (seventh step).

Then, as the purge gas, Ar gas of a flow rate of 360 mL/min (sccm) was introduced into the chamber 21 for 10 seconds and the inside of the chamber 21 was purged (eighth step).

The WN film was obtained by repeating the fifth to seventh steps 13 times while keeping the pressure in the chamber 21 at 20 Pa. With respect to the WN film, a sheet resistance was measured by a four edge measuring method, the film thickness was measured by XRF, so that resistivity was estimated therefrom. As a result, the sheet resistance was about 310 Ω/sq, the film thickness was 9 nm, and the resistivity was 278 μΩ·cm. The N/W composition ratio of the film measured by the RBS was about 0.5, and the oxygen concentration was 3.3 atoms %. By using the WN film, gate electrodes were formed on SiO2 films of which thickness were respectively 2 nm, 5 nm and 9 nm, and the work function of the gate electrodes was measured. The measured work function was 4.7 eV and it was confirmed that the formed gate electrodes could serve as gate electrodes.

### Example 4

In the apparatus shown in FIG. 7, the susceptor 22 was heated to 672° C. in advance, and a wafer W having a diameter of 300 nm was loaded on the susceptor 22 by the transfer device. Then, Ar gas as the carrier gas and Ar gas as the dilution gas were supplied in a ratio of (carrier gas Ar)/(dilution gas Ar)=60/300 mL/min (sccm), and W(CO)₆ gas was introduced into the chamber 21 for 5 seconds, whereby an ultra-thin W film was formed on the wafer W (fifth step).

Next, Ar gas as the purge gas of a flow rate about 360 mL/min (sccm) was introduced into the chamber 21 for 10 seconds and the inside of the chamber 21 was purged (sixth step).

After that, NH₃ gas and Ar gas as the dilution gas were supplied in a ratio of NH₃/(dilution gas Ar)=310/50 mL/min (sccm), and the NH₃ gas was introduced into the chamber 21 for 10 second, so that a WN film was formed by nitriding the W film formed at the fifth step (seventh step).

Then, as the purge gas, Ar gas of a flow rate 360 mL/min (sccm) was introduced into the chamber 21 for 10 seconds and the inside of the chamber 21 was purged (eighth step).

The WN film was obtained by repeating the fifth to eighth steps 11 times while keeping the pressure in the chamber 21 at 133 Pa. With respect to the WN film, the sheet resistance was measured by the four edge measuring method, the film thickness was measured by XRF, whereby the resistivity was estimated therefrom. As a result, the sheet resistance was 1,990 Ω/sq, the film thickness was 12 nm, and the resistivity was 2,390 μΩ·cm. The N/W composition ratio of the film measured by RBS was about 0.5. By using the WN film, gate electrodes were formed on SiO2 films of which outer film was formed with HfSiO and thickness was respectively 2 nm, 5 nm and 9 nm. Then, the work function of the gate electrodes was measured. The measured work function was 4.9 eV and it was confirmed that the formed gate electrodes could serve as gate electrodes.

### Comparative Example 1

In the apparatus shown in FIG. 7, the susceptor 22 was heated to 672° C. in advance, and a wafer W having a diameter of 300 mm was loaded on the susceptor 22 by the transfer device. Then, Ar gas as the carrier gas, Ar gas as the dilution gas and NH₃ gas in a flow rate of (carrier gas Ar)/(dilution gas Ar)/NH₃=90/150/100 mL/min (sccm) were supplied for 32 seconds while maintaining the pressure in the chamber 21 at 20 Pa, whereby a WN film was obtained. With respect to the WN film, the sheet resistance was measured by the four edge measuring method, and the film thickness was measured by XRF, whereby the resistivity was estimated therefrom. As a result, the sheet resistance was 282 Ω/sq, the film thickness was 10.6 nm, and the resistivity was 299 μΩ·cm. The oxygen amount in the WN film had a quite high value of 21%.

### Comparative Example 2

In the apparatus shown in FIG. 7, the susceptor 22 was heated to 672° C. in advance, and a wafer W having a diameter of 300 mm was loaded on the susceptor 22 by the transfer device. Then, Ar gas as the carrier gas and Ar gas as the dilution gas in a flow rate of (carrier gas Ar)/(dilution gas Ar)=310/50 mL/min (sccm) were supplied for 65 seconds while maintaining the pressure in the chamber 21 at 20 Pa, and the W film was formed. Then, the W film was nitrided by supplying NH₃ gas and Ar gas as the dilution gas in a flow rate of NH₃/(dilution gas Ar)=310/50 mL/min for 10 seconds. With respect to the WN film, the sheet resistance was measured by the four edge measuring method, and the film thickness was measured by XRF, whereby the resistivity was estimated therefrom. As a result, the sheet resistance was 79.5 Ω/sq, the film thickness was 9.6 nm, and the resistivity was 76 μΩ·cm. The surface of the WN film was measured by XRF, and it was confirmed that N existed only in the surface of the WN film.

The present invention is not limited to the above-mentioned embodiments, but various modifications and changes thereof may be made.

For example, although in the above-mentioned embodiment the purging was performed both after supplying the W(CO)₆ gas and the Si-containing gas, the purging may be performed only after supplying the W(CO)₆ gas. Moreover, although NH₃ was used as the N-containing gas for forming the WN film, the N-containing gas is not limited thereto, but may be other N-containing gas such as hydrazine (HN₂NH₂), monomethylhydrazine (CH₃)HNNH₂ and the like. Further, the methods for forming the WSi film and the WN film have been described individually, however, a composite film thereof may be formed. Furthermore, although the W-based film in accordance with the embodiments of the present invention has been applied to the gate electrode of the MOS type semiconductor in the Examples, the W-based film may be employed for other uses.

### INDUSTRIAL APPLICABILITY

The W-based film formed by the methods in accordance with the embodiments of the present invention is suitable for forming a gate electrode of a MOS type semiconductor.

What is claimed is:

1. A method for forming a W-based film comprising:
disposing a substrate in a processing chamber;
forming a WSi film by alternately repeating deposition of W by introducing W(CO)₆ gas into the processing chamber and silicidation of the W or deposition of Si by introducing a Si-containing gas into the processing chamber; and
purging the processing chamber between the W(CO)₆ gas supply and the Si-containing gas supply.

2. The method of claim 1, wherein the deposition of the W by introducing the W(CO)₆ gas, the purge of the processing chamber, the silicidation of the W or the deposition of the Si by the Si-containing gas, and the purge of the processing chamber are repeated twice or more in that order.

3. The method of claim 1, wherein the Si-containing gas is selected from SiH₄, Si₂H₆, TDMAS, and BTBAS.

4. The method of claim 1, wherein the purge of the processing chamber is performed by using a purge gas selected from Ar gas, He gas, N₂ gas, and H₂ gas.

5. The method of claim 1, wherein Si/W composition of the WSi film is changed by controlling a flow rate of the Si-containing gas and a ratio of a W(CO)₆ gas supplying time and a Si-containing gas supplying time.

6. The method of claim 1, wherein the deposition of the W by introducing the W(CO)₆ gas is performed at a temperature equal to or higher than a temperature at which the W(CO)₆ gas is decomposed.

7. A method for forming a gate electrode comprising:
disposing a silicon substrate formed with a gate insulating film thereon in a processing chamber;
forming a gate electrode by forming a WSi film on the gate insulating film of the silicon substrate by alternately repeating deposition of W by introducing W(CO)₆ gas into the processing chamber and silicidation of the W or deposition of Si by introducing a Si-containing gas into the processing chamber; and
purging the processing chamber between the W(CO)₆ gas supply and the Si-containing gas supply.

8. The method of claim 7, wherein Si/W composition of the WSi film is changed by controlling a flow rate of the Si-containing gas and a ratio of a W(CO)₆ gas supplying time and a Si-containing gas supplying time, whereby a work function is changed in a range of from n type use to p type use.

9. A method for manufacturing a semiconductor device comprising:
forming a gate insulating film on a silicon substrate;
disposing a silicon substrate on which the gate insulating film is formed in a processing chamber;
forming a gate electrode by forming a WSi film on the gate insulating film of the silicon substrate by alternately repeating deposition of W by introducing W(CO)₆ gas into the processing chamber and silicidation of the W or deposition of Si by introducing Si-containing gas into the processing chamber;
purging the processing chamber between the W(CO)₆ gas supply and the Si-containing gas supply; and
forming an impurity diffusion region around the semiconductor substrate.

10. A method for forming a W-based film comprising:
disposing a substrate in a processing chamber;
forming a WN film by alternately repeating deposition of W by introducing W(CO)₆ gas and nitridation of W by introducing an N-containing gas into the processing chamber; and
purging the processing chamber between the W(CO)₆ gas supply and the N-containing gas supply.

11. The method of claim 10, wherein the deposition of the W by introducing the W(CO)₆ gas, the purge of the processing chamber, the nitridation of the W by introducing the N-containing gas, and the purge of the processing chamber are repeated twice or more in that order.

12. The method of claim 10, wherein the N-containing gas is NH₃ gas.

13. The method of claim 10, wherein the purge of the processing chamber is performed by using a purge gas selected from Ar gas, He gas, N₂ gas, and H₂ gas.

14. The method of claim 10, wherein a thickness of the W film formed per every single W deposition by introducing the W(CO)₆ gas is 5 nm or less.

15. The method of claim 10, wherein the deposition of the W by introducing the W(CO)₆ gas is performed at a temperature equal to or higher than a temperature at which the W(CO)₆ gas is decomposed.

16. A method for forming a gate electrode comprising:
disposing a silicon substrate formed with a gate insulating film thereon in a processing chamber;
forming a gate electrode by forming a WN film on the gate insulating film of the silicon substrate by alternately repeating deposition of W by introducing W(CO)₆ gas into the processing chamber and nitridation of the W by introducing N-containing gas into the processing chamber; and
purging the processing chamber between the W(CO)₆ gas supply and the N-containing gas supply.

17. A method for manufacturing a semiconductor device comprising:
forming a gate insulating film on a silicon substrate;
disposing a silicon substrate formed with the gate insulating film thereon in a processing chamber;
forming a gate electrode by forming a WN film on the gate insulating film of the silicon substrate by alternately repeating deposition of W by introducing W(CO)₆ gas into the processing chamber and nitridation of the W by introducing N-containing gas into the processing chamber;
purging the processing chamber between the W(CO)₆ gas supply and the N-containing gas supply; and
forming an impurity diffusion region around the semiconductor substrate.

18. A computer readable-storage medium for storing therein a computer-executable control program, wherein, when executed, the control program controls a film forming apparatus to perform a method for forming a W-based film comprising:
disposing a substrate in a processing chamber;
forming WSi film by alternately repeating deposition of W by introducing of W(CO)₆ gas into the processing chamber and silicidation of the W or deposition of Si by introducing Si-containing gas into the processing chamber; and
purging the processing chamber between the W(CO)₆ gas supply and the Si-containing gas supply.

19. A computer readable-storage medium for storing therein a computer-executable control program, wherein, when executed, the control program controls a film forming apparatus to perform a method for forming a W-based film comprising:
disposing a substrate in a processing chamber;
forming a WN film by alternately repeating deposition of W by introducing W(CO)₆ gas into the processing chamber and nitridation of the W by introducing N-containing gas into the processing chamber; and
purging the processing chamber between the W(CO)₆ gas supply and the N-containing gas supply.
